(19) United States
(12) Patent Application Publication
(10) Pub. No.: US 2016/0150637 A1
(43) Pub. Date: May 26, 2016

(54) DEVICE KIT AND METHOD FOR ABSORBING LEAKAGE CURRENT

(71) Applicant: Amichai ZIV, NATANYA (IL)

(72) Inventor: Amichai ZIV, NATANYA (IL)

(21) Appl. No.: 14/442,470

(22) PCT Filed: Nov. 13, 2013
(86) PCT No.: PCT/IL2013/050938

§ 371 Date: May 13, 2015

Related U.S. Application Data
(60) Provisional application No. 61/726,587, filed on Nov. 15, 2012.

(51) Int. Cl. H05K 1/02; B05C 17/005; B43K 8/02; B43K 19/00; H05K 3/28; H01C 7/00

(52) U.S. Cl. CPC H05K 1/0213; H05K 3/28; H01C 7/00; B43K 8/02; B43K 19/00; B05C 17/005

(57) ABSTRACT

The present invention relates to a kit devise, and method for absorbing leakage current in an electronic circuit including at least one switch and at least one load by using an absorbing device, an absorbing material or an absorbent marking device, wherein the absorbent marking device is configured to mark or attach an absorbing material on the circuit or on the load.

### RELATED APPLICATION

The present invention gains priority from U.S. Provisional Patent Application No. 61/726,587 filed on Nov. 15, 2012.

### FIELD OF THE INVENTION

The present invention relates to the field of electrical circuits and improving the performance of electrical circuits. In one embodiment, the invention relates to improving the performance of electrical circuits controlled by electronic switches.

### BACKGROUND OF THE INVENTION

The operation of specific electrical devices by remote control is well known in the art, for example to control televisions, videos, and air-conditioners. In recent years house automation systems have been introduced, wherein remote control switches are used to replace or supplement the standard wall mounted switches, for example, to turn on/off or dim lights.

Remote control switches may be controlled through the use of a keypad or a wireless remote controller or may be pre-programmed to perform functions automatically, for example turning lights on and off at selected times. These switches typically include electronic components such as wireless relay receiver boards, processors and sometimes a light source for backlighting the switch for a decorative effect. Therefore, remote control switches require electrical power to function and to control the status of a load.

In some cases the power for the functionality of a remote control switch is provided from the main power source that powers the load being controlled by the switch. Typically, a remote control switch draws a low current electrical signal from the power lines. Usually the switch is connected serially to the load and doesn't have a zero/neutral line, only the phase that goes to the load is controlled by the switch.

A switch which includes electronic components and which is itself powered for its function, consumes a small current for the switch's circuitry. This Leakage current is any current that flows when the ideal current is zero. The leakage current may affect loads in a circuit even though it may be a very low current. Loads, such as illumination elements, may be unintentionally powered due to the leakage current. This can cause the unwanted situation where light bulbs flicker or even stay turned on when the switch is OFF.

### SUMMARY OF THE INVENTION

It is therefore an object of the present invention to provide a device and method for use in conjunction with a circuit including a load, such as a light bulb and a switch including electronic components and which is itself powered for its function, that will prevent the unwanted situation where the light bulb flickers or even remains turned on.

It is another object of the present invention to provide a device, kit and method to solve the leakage current problem. The device and kit should be cost effective, simple to handle by electrician as well as unprofessional electronic consumer. Other objects of the invention will become apparent as the description of the invention proceeds.

According to one embodiment the device includes a current absorbing element and connecting elements configured to connect to terminals of the load or load holder, for example, to terminals of a light bulb.

According to another embodiment of the present invention there is provided an absorbent material that can be easily applied, for example directly to a load or load holder in a circuit. This material absorbs the leakage current and prevents the unwanted activation of loads.

According to an aspect of some embodiments of the present invention there is provided a kit for absorbing leakage current in an electronic circuit comprising a load, said kit comprises:
an absorbing material; and
an absorbent marking device, wherein said absorbent marking device is configured to mark said absorbing material on said circuit or on said load.

In an embodiment the marking device is selected from a group consisting of: a pen, white out dispenser, a marker, a sticker, bottle with brush or applicator.

In an embodiment the pen comprises a tip or nib, configured to apply the absorbing material.

In an embodiment the pen comprises a button configured to dispense the absorbing material by the press of the button.

In an embodiment the pen comprises an electrical component configured to turn on/off or control the amount of the absorbing material released from the pen.

In an embodiment the pen comprises a screen configured to monitor the temperature and amount of the material inside the pen.

In an embodiment the absorbing material comprises a dielectric or resistive material.

In an embodiment the dielectric or resistive material is of a range of 0.5 MΩ-100 KΩ.

In another embodiment the load may be a light bulb.

In an embodiment the switch may comprise electric components.

In an embodiment said electric components are selected from the group consisting of: Microcontroller, and an RF receiver.

According to a second aspect of the present invention there is provided a method for absorbing leakage current in an electronic circuit said circuit comprising at least one switch and at least one load, the method comprising:
providing an absorbent marking device, said device comprises an absorbent material configured to absorb a leakage current in the electronic circuit; and
marking the load or the circuit with the absorbent material.

According to a third aspect of the present invention there is provided a device for absorbing leakage current, the device comprising a current absorbing element and connecting elements configured to connect to load or load holder terminals.

In an embodiment the current absorbing element comprises a capacitor, resistor or combination thereof.

In an embodiment the current absorbing element is a conductive color ink, or conductive glue or combination thereof.

According to another embodiment the device may comprise a support, said support having the absorbing element integrated thereon.

In an embodiment the support is a PCB.

In an embodiment the connecting elements extend from the support.

In an embodiment one of the connecting elements is integrated onto the support and one of the connecting elements extends from the support.

In another embodiment the connecting elements comprise a loop or a snap.

In an embodiment the current absorbing element comprises a dielectric or resistive material.

In an embodiment the current absorbing element comprises filters, fuses or snubbers.

In an embodiment the current absorbing element comprises electronics parts.

In an embodiment the electronic parts comprise a zener diode, a diac or other voltage clamping circuitry, or combination thereof.

In an embodiment the current absorbing element is assembled in the load or load holder.

In an embodiment the current absorbing element is selected from the group consisting of a conductive color conductive color ink, glue or other electric material applied by unique pen or painting device or applicator.

According to a fourth aspect of the present invention there is provided device for absorbing leakage current the device comprising:
a current absorbing element, said current absorbing element comprises a material with impedance, and wherein said absorbing element is configured to connect to load terminals or to a load holder.

In an embodiment the impedance is between 100 K-1 M ohm.

In an embodiment the material is a conducted PVC or silicon or other plastics with impedance.

### BRIEF DESCRIPTION OF THE FIGURES

The invention will now be described in relation to certain examples and embodiments with reference to the following illustrative figures so that it may be more fully understood. In the drawings:

FIG. 1 is a schematic representation of an electric circuit including a device for absorbing leakage current, according to embodiments of the invention;

FIGS. 2A-C are a schematic illustrations of a device for absorbing leakage current, according to embodiments of the invention;

FIGS. 3A-B are schematic illustrations of a device for absorbing leakage current, operable according to embodiments of the invention.

FIGS. 4A-C are schematic illustrations of a material for absorbing leakage current according to embodiments of the invention;

FIG. 5A is a schematic illustration of an absorbent material operable directly on the load of electric circuit, according to embodiments of the invention; and

FIG. 5B is a schematic illustration of an absorbent material operable directly on a socket, according to embodiments of the invention.

### DETAILED DESCRIPTION OF THE INVENTION

The present invention, in some embodiments thereof, relates to a devise, a kit and method for absorbing leakage current in an electronic circuit including at least one switch and at least one load by using an absorbing device or an absorbent marking device comprising an absorbing material configured to mark the absorbing material on the circuit or on the load.

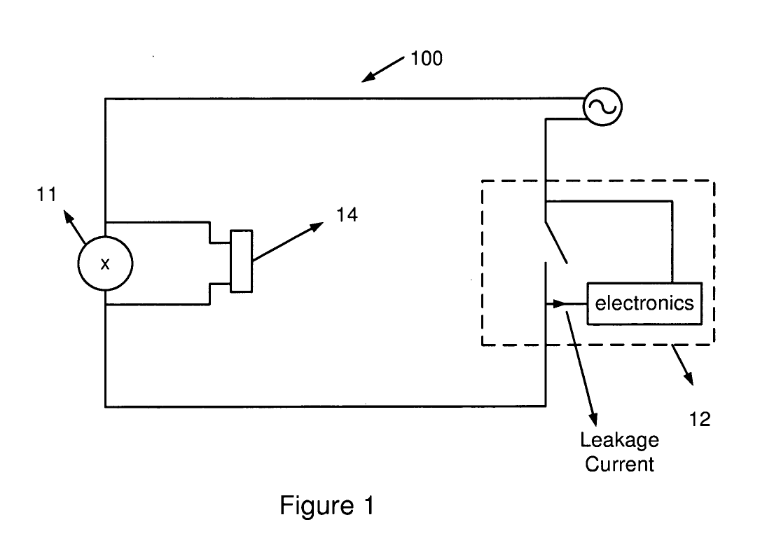

The invention will now be described by way of examples, and without limiting the generality of the foregoing. Reference is made to FIG. 1A which schematically describes an electric circuit controlled for example by a remote control switch, according to one embodiment of the invention. Circuit 100 connects to wires of a remote control power switch in series to the load 11 that is controlled by the power switch. There is a switch element 12 in the circuit that enables electric current flow when the switch element 12 is ON and disconnects the load when the switch element 12 is OFF. The switch element 12 may be a remotely controlled switch or any other electronic switch that includes electric components, such as a Microcontroller, RF receiver push button switch with a backlight which consumes a small current even in an OFF state.

When switch element 12 is OFF, for example when it is desired to shut off load 11 (e.g. a light bulb), leakage current may develop in the switch element 12 itself. This leakage current may eventually, cause the load 11 to flicker on and off. Alternatively, the leakage current may power load 11 if load 11 has a very low current consumption. This may cause unwanted turning on of load 11 even when the switch element 12 is OFF.

According to Ohm's Law (V=I*Z), the current leakage problem which the present invention aim to solve may be represented by the following relationship:

Vblink>Ileakage*Z (1)
where:
Vblink is the amount (in volts) needed to induce blinking on the load;
Ileakage is the amount of current (in ampers) unintentionally being released in the circuit;
and Z is the impedance.

Vblink occurs when the product of Ileakage and the Impedance (i.e. ‘Z’) reach a figure above threshold, causing enough volts to induce blinking of the load. In order to prevent Vblink, it must be below threshold. This will occur when the product of both I and Z is below the threshold. Since the leakage current is kept as low as possible (it can't be zero), the parameter that may be controlled is Z.

To avoid these problems, the present invention provides a number of solutions and embodiments to control and manipulate the ‘Z’ value at the circuit 100, thus preventing Vblink to reach the unwanted threshold which induces blinking of the load. According to one embodiment as shown in FIG. 1, a leakage current absorbing device 14, is added to the circuit to control the ‘R’ value at the current 100 and absorb the leakage current to prevent the leakage current from unintentionally powering the load 11.

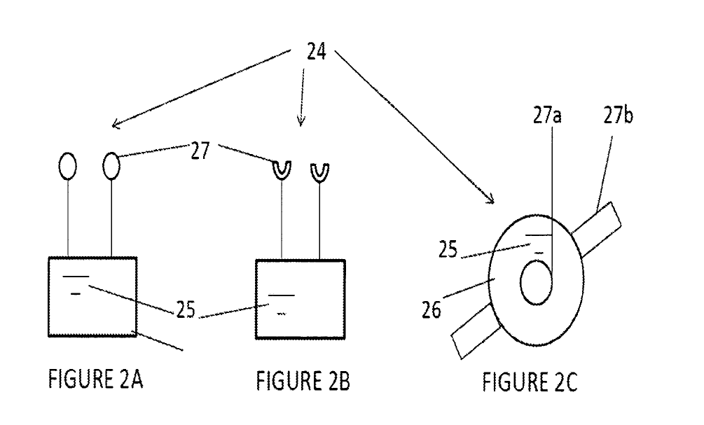

The device 14 may be unobtrusively added to the circuit, for example, by attaching it to the connections or terminals of load 11. This way, an existing circuit and switch may be used without having to adjust or change the circuit due to leakage current effects. Leakage current absorbing devices according to embodiments of the invention are schematically illustrated in FIGS. 2A, 2B and 2C.

The device 24 includes one or more current absorbing elements 25, such as a capacitor and/or a resistor, for example, the current absorbing element 25 may include a small resistor in series with a small capacitor, essentially providing a filter, fuse or snubber to suppress the rapid rise in voltage that may be caused by leakage current. The use of a resistor enables to use a very small capacitor, suitable for adding unobtrusively to an existing load or circuit.

The current absorbing element 25 may be made of a dielectric or resistive material to “absorb” the leakage current. The current absorbing element 25 may be made of a material that can act as a contact as well as a current absorbing element.

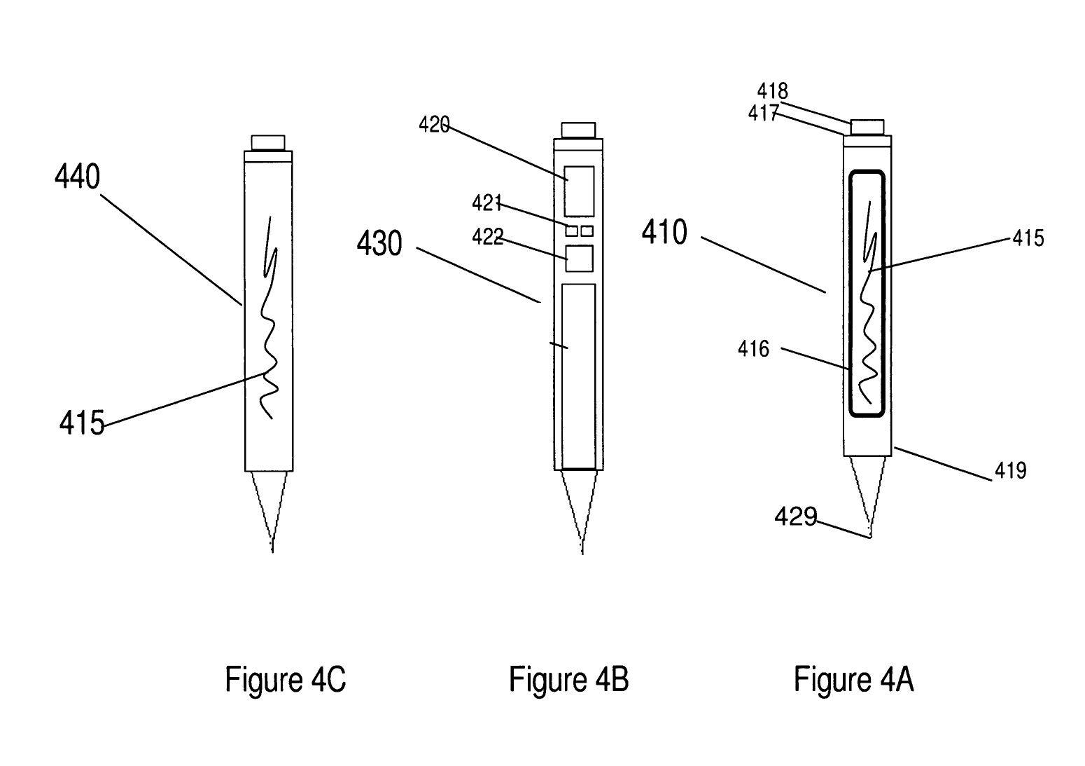

According to one embodiment the resistive or the dielectric material may also be a special conductive or dielectric color ink or glue etc. applied by unique pen or painting device or applicator as will be further illustrated in FIGS. 4A-C.

The current absorbing element 25 may also include electronics parts such as a zener diode or diac or other voltage clamping circuitry, or combination thereof. Such electronic parts may limit the maximum voltage on the load while the switch 12 is in an OFF state.

The a current absorbing element 25 may be embedded or printed onto a support 26 such as a printed circuit board (PCB) and is in electrical communication with connecting elements 27 which typically extend from the support 26 and which are configured to connect to terminals of a load, e.g., light bulb terminals.

The connecting elements 27 may be designed to easily attach onto the load terminals. According to one embodiment the connecting elements 27 are loops (FIG. 2A) for being threaded onto the terminals. According to another embodiment, the connecting elements 27 are snaps (FIG. 2B) for snapping onto the terminals. Other shapes and designs of connecting elements may be used.

According to another embodiment (FIG. 2C) a device 24 is made of a typically round support 26 (such as a flexible PCB) which has embedded or printed on it an absorbing element 25 (such as one or more capacitors and/or resistors) and also has integrated on it a connecting element 27a. Another connecting element 27b extends radially from the support 26. For example, connecting element 27b may be a band surrounding the support 26 or may include tabs or flaps extending from the support 26.

The connecting elements are typically made of electrically conductive material so as to enable electric connection with the load terminals and circuit. The connecting elements may be made of a dielectric material that consumes AC (Alternating current) current.

When a leakage current absorbance device, such as device 24, is in electric communication with the circuit which includes an electronic switch and a load, the device 24 will absorb the leakage current caused by the electronic switch and thus, unintentional flickering and activity of the load will be avoided.

The absorbing elements 25 may include one or more capacitors or one or more resisters or a combination of capacitors and resistors and electronic parts, as described above. Capacitors may be advantageously used as absorbing elements since they receive the leakage current and don't consume active energy, hence do not heat up as opposed to resistors.

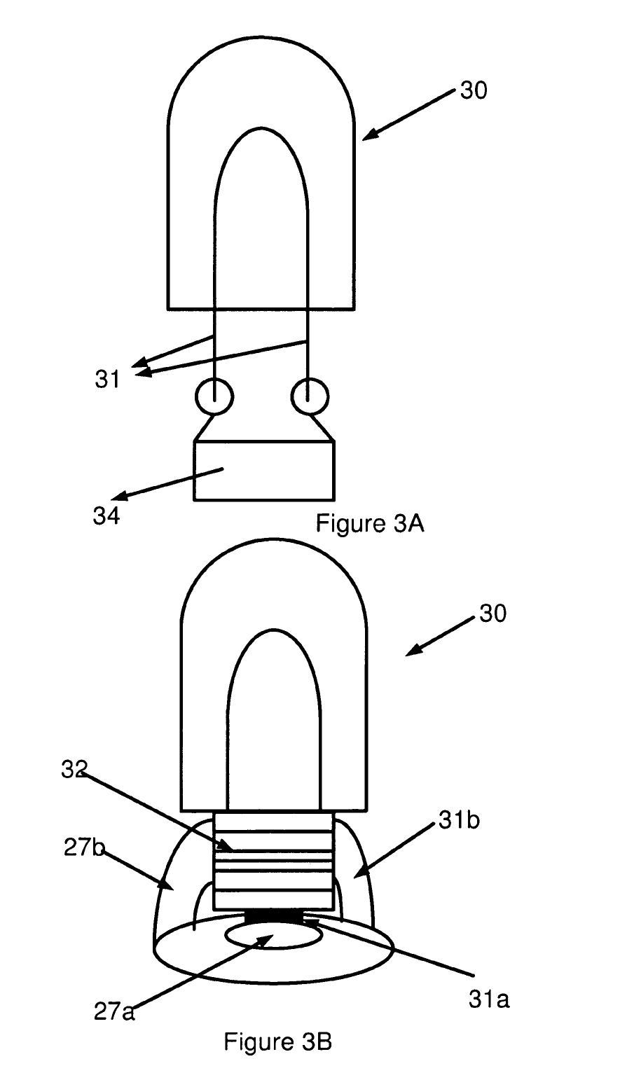

FIGS. 3A and 3B schematically illustrate examples of a load having attached onto it a leakage absorbing device according to embodiments of the invention.

For example, a load may be a light bulb 30 having terminals 31 (FIG. 3A) or a light bulb 30 having a screw base 32 (FIG. 3B).

A leakage absorbing device 34 according to embodiments of the invention may be attached to or assembled on and in electrical communication with the bulb 30 by snapping onto or being threaded onto terminals 31 or by otherwise attaching to terminals 31, prior to placing the light bulb 30 in its socket.

Alternatively, the device 34 may be placed on the screw base 32 of the bulb 30 such that one connecting element 27a is in electric communication with the bulb terminal 31a at the bottom of the screw base. The other connecting element 27b may be wrapped around the screw part 31b of the screw base or may be otherwise folded to be in contact (and electric communication) with the screw part of the screw base.

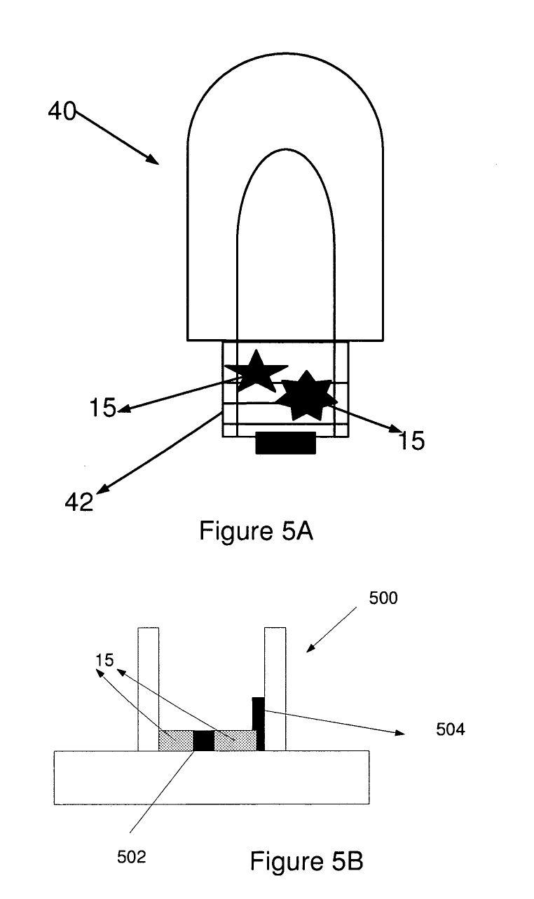

Alternatively, an absorbing material may unobtrusively and with relative ease be added to the circuit. For example, as illustrated in FIGS. 1 and 5A, an absorbing material 15 may be added to the load 11 (e.g. bulb 40) by painting or marking it, for example directly on to the load 11 or where the load connects to the circuit. According to one embodiment of the invention as shown in FIG. 5, the absorbing material 15 may be painted around the screw part 42 of a bulb 40.

According to some embodiments as shown in FIG. 5B the absorbing material 15 or the absorbing device 24 may be attached or painted to or into a socket or bulb holder 500. For example, the absorbing material or the absorbing device may be attached to the socket's terminals 502 and 504 at the bottom of the socket 500.

According to another embodiment the absorbing material may be made of a conductive silicon, or PVC ((polyvinyl chloride) shaped in a way that it may be attached or for example screwed directly to the screw part 42 of bulb 40.

The absorbing material or absorbing device may be attached on or to the socket or Bulb holder 500.

According to some embodiments of the invention, in a circuit including a load which is typically flickering at 50V and a typical leakage current is 100 μA, the value of ‘Z’ (i.e. the impedance) e.g. Rbypass needed to prevent the blinking is:

Rbypass<Vblink/Ileakge=50V/100 μA=0.5 MΩ (2)

Therefore, according to some embodiments of the invention, the absorbent material 15 added or attached to the circuit should include a conductor dye or color including a resistance or impedance material in the range of 0.5 MΩ-100 KΩ in order to create the necessary resistance required in preventing Vblink.

According to some embodiments of the present invention, the absorbent material 15 can be added directly to the load or the circuit through the use of a marker or pen or any such device containing the material 15. The absorbent material is easier to employ as it does not require additional wiring, as well as it is more cost effective and time efficient.

Reference is made to FIG. 4A, which schematically illustrates a kit including a device, such as an absorbent marking device 410 configured to mark and color the load or the circuit with an absorbent material 415. According to one embodiment as shown in FIG. 4A the marker device 410 may be in the form or activated as a writing tool such a pen, pencil, or a marker. However, the absorbent marking device may be or may include a white-out bottle with brush or any other instrument used for writing or marking such as a sticker. The absorbent marking device 410 may include: a housing 419 a tubular body or any other structure or container 416 that can be filled up with an absorbing material 415 and refilled when necessary; a removable cap 417 allowing the refill; a delivery button 418 for dispensing; a nib such as a pen tip 429 through which the absorbing material may flow.

According to another embodiment of the invention as shown in FIG. 4B, the absorbent marking device may be in the form or activated as a marker 430. The marker 430, can be electrically operated and therefore contains various switches on its sides, such as: an on/off switch 420, certain switches that control the dispensing pressure 421 and/or any other switch serving instrument. The marker 430 may include a screen 422 that indicates various relevant aspects and measurements (i.e. temperature as well as amount of material remaining in tubular body) for effectively utilizing and refilling the instrument.

According to some embodiments of the invention, the absorbent marking device can be a pencil 440, holding the absorbing material 415 as seen in FIG. 4C.

According to some embodiments, the absorbent marking device is a bottle containing the absorbing material, together with a screw cap along with a brush or other dispersing utensils (e.g. a white-out bottle) for dispensing the absorbing material.

According to another embodiment, the absorbent marking device can be a marking pen or a felt-tip pen, allowing the absorbing material dispersion according to the pressure applied by the user to the tip of the device.

The absorbing material 15 may include one or more current absorbing elements, such as: graphite or PVC.

It is expected that during the life of a patent maturing from this application many relevant systems and methods will be developed and the scope of the terms absorbing, leakage current, switch unit including electric components intended to include all such new technologies a priori.

As used herein the term “about” refers to +−10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

The word “exemplary” is used herein to mean “serving as an example, instance or illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A kit for absorbing leakage current in an electronic circuit, said electronic circuit comprising a load, and wherein said kit comprises:
an absorbing material; and
an absorbent marking device, wherein said absorbent marking device is configured to mark said absorbing material on said electronic circuit or on said load or on said load holder or connector.

2. The kit according to claim 1, wherein said device is selected from a group consisting of: a pen, pencil, white out dispenser, a marker, a sticker, bottle with a brush or applicator.

3. The kit according to claim 2, wherein the pen comprises a tip or nib, configured to apply the absorbing material.

4. The kit according to claim 2, wherein the pen comprises a button configured to dispense the absorbing material by the press of the button.

5. The kit according to claim 2 wherein the pen comprises an electrical component configured to turn on/off or control the amount of the absorbing material released from the pen.

6. The kit according to claim 2 wherein the pen comprises a screen configured to monitor the temperature and amount of the material inside the pen.

7. The kit according to claim 1 wherein the absorbing material comprises a material with electric impedance.

8. The kit according to claim 1 wherein the impedance material is of a range of 1 MΩ-100 KΩ.

9. The kit according to claim 1, wherein the load is a light bulb.

10. The kit according to claim 1, wherein the switch comprises electric components.

11. The kit according to claim 10, wherein said electric components are selected from the group consisting of: Microcontroller, and an RF receiver.

12. A method for absorbing leakage current in an electronic circuit said circuit comprising at least one switch and at least one load, the method comprising:
a. providing an absorbent marking device, said device comprises an absorbent material configured to absorb a leakage current in the electronic circuit.
b. marking the load or the electronic circuit with the absorbent material.

13. A device for absorbing leakage current the device comprising a current absorbing element and connecting elements configured to connect to load terminals or to a load holder.

14. The device of claim 13 wherein the current absorbing element comprises a capacitor, resistor or combination thereof.

15. The device of claim 13 wherein the current absorbing element is a conductive color ink, or conductive glue or combination thereof.

16. The device of claim 13 further comprising a support, said support having the absorbing element integrated thereon.

17. The device of claim 16 wherein the support is a PCB or a flexible PCB.

18. The device of claim 16 wherein the connecting elements extend from the support.

19. The device of claim 16 wherein one of the connecting elements is integrated onto the support and one of the connecting elements extends from the support.

20. The device of claim 13 wherein the connecting elements comprise a loop or a snap.

21. The device of claim 13 wherein the current absorbing element comprises a dielectric or resistive or impedance material.

22. The device of claim 13 wherein the current absorbing element comprises filters, fuses or snubbers.

23. The device of claim 13 wherein the current absorbing element comprises electronics parts.

24. The device of claim 23 wherein the electronic parts comprise a zener diode, a diac or other voltage clamping circuitry, or combination thereof.

25. The device of claim 13 wherein the current absorbing element is assembled in the load or load holder.

26. The device of claim 13 wherein the current absorbing element is a conductive color conductive color ink, or glue or other electric material.

27. The device of claim 13 wherein the load comprises a light bulb.

28. A device for absorbing leakage current said device comprising:
a current absorbing element, said current absorbing element comprises a material with impedance configured to connect to load terminals or to a load holder.

29. The device of claim 28 wherein the impedance is between 100 K-1 M ohm.

30. The device of claim 28 wherein the material is a conducted PVC or silicon or other plastics with impedance.
